(19) United States
(12) Patent Application Publication
(10) Pub. No.: US 2018/0277408 A1
(43) Pub. Date: Sep. 27, 2018

(54) A METHOD AND APPARATUS FOR PICKING COMPONENTS FROM A CARRIER

(71) Applicant: ISMECA SEMICONDUCTOR HOLDING SA, La Chaux-de-Fonds (CH)

(72) Inventor: Laurent ABBET, La Chaux-de-Fonds (CH)

(73) Assignee: ISMECA SEMICONDUCTOR HOLDING SA, La Chaux-de-Fonds (CH)

(21) Appl. No.: 15/762,231

(22) PCT Filed: Feb. 2, 2016
(86) PCT No.: PCT/IB2016/050519

§ 371 Date: Mar. 22, 2018

(51) Int. Cl. H01L 21/67; H01L 21/66; G01R 31/28

(52) U.S. Cl. CPC H01L 21/67271; G01R 31/2831; H01L 22/20

(57) ABSTRACT

According to the present invention there is provided a method of handling components on a carrier, the method comprising the steps of, providing a carrier having a plurality of components supported thereon; testing the plurality of components to identify good components and bad components, wherein good components are those components which successfully pass testing and bad components are those components which fail testing; defining a first good components to be picked from the carrier; defining an integer number of components to be a jump value; locating a pickup head, which is operable to pick components from the carrier, above a first reference position on the carrier; identifying one or more good components, which are within the jump value from the first reference position; moving the pickup head or the carrier so that the pickup head is centered above at least one of the one or more good components; moving the pickup head or the carrier, so that the pickup head is moved from above said at least one of the one or more good components to above the defined first good component to be picked without picking said at least one of the one or more good components; centering the pickup head above the first good components to be picked; picking the first good components to be picked. There is further provided a corresponding component handling apparatus.

### FIELD OF THE INVENTION

The present invention concerns a method and apparatus for picking components (such as dies) from a carrier (such as a wafer), and in particular a method and apparatus which involves moving the carrier with respect to a pickup head, or moving pickup head with respect to the carrier, so that the pickup head is moved from a starting position to a component to be picked, whereby the pickup head is aligned with respect to a component which is located along a path between the pickup heads starting position and the component to be picked, so that the pickup head undergoes at least one intermediate alignment with respect to a component on the wafer before the pick p head is centred above the component to be picked.

### DESCRIPTION OF RELATED ART

Devices on wafers are picked a pickup head. Typically the wafer with devices is moved into a picking station where the pickup head is located. The wafer will have a reference fiducial, and upon entering the picking station the wafer is aligned so that the reference fiducial is centred beneath the pickup head.

After the wafer has been aligned the pickup head is moved from above the reference fiducial so that it is centred above the first device which is to be picked.

Existing solutions do not provide for reliable centering of the pickup head above a predefined first device to be picked; for example, this can be due to the fact that the wafer comprise many devices having a small size making is difficult to accurately position the pickup head over one single predefined first device to be picked; in particular unreliable centering of the pickup head above a predefined first device to be picked especially occurs when the pickup head is required move a large distance from its starting position to the predefined first device to be picked. Consequently, existing solutions do not provide for reliable picking of a predefined first device to be picked, from the wafer. Also, as a result of the of unreliable centering above the predefined first device to be picked, existing solutions also then fail to provide for reliable centering of the pickup head above subsequent devices on the wafer to be picked since the movement of the pickup head typically uses the position of the predefined first device as a reference position from which to determine the positions of subsequent devices on the wafer to be picked.

In one existing solution, the movement of the pickup head from above the reference fiducial so that it is centred above the first device to be picked, is done based on the known size of the devices and the spacing which exists between the devices on the wafer; for example assuming that the edge of the wafer defines the reference fiducial, and that the device size is 2 mm and the spacing between the devices on the wafer is 1 mm; then if the first device to be picked is the 3^{rd} device from the outermost edge of the wafer, then the system moves the pickup head 7 mm (i.e. 2 mm over the 1^{st} device+1 mm over the 1^{st} spacing+2 mm over the 2^{nd} device+1 mm over the 2^{nd} spacing+1 mm to move over first half of the device to be picked so that the pickup head is centred with respect to the device) from the edge of the wafer, so that it is centred above the first device to be picked.

However the movement of the pickup head from above the reference fiducial so that it is centred above the first device to be picked will only be successful provided each of the intervening devices which lie along the path between the reference fiducial and first device to be picked are not displaced; if a device along the path is displaced, then all devices along the path, between the displaced device and first device to be picked, will also be displaced by an equivalent amount. Moreover if more than one intervening device along the path is displaced, then there will be an accumulation of displacements, and the first device to be picked will be displaced by an amount which is substantially equal to the sum of all displacement amounts of each device along the path.

Accordingly due to the displacement of intervening devices which lie along the path between the reference fiducial and first device to be picked the pickup head may not be accurately centred above the first device to be picked.

After the first device has been picked, the pickup head will be moved to be centred under subsequent device to be picked; a similar problem will arise, thus the pickup head will not be accurately centred above subsequent devise to be picked.

It is one aim of the present invention to obviate one or more of the above-mentioned disadvantages which are associated with existing picking methods of picking systems.

### BRIEF SUMMARY OF THE INVENTION

According to the invention, these aims are achieved by means of a method of handling components on a carrier, the method comprising the steps of, providing a carrier having a plurality of components supported thereon; testing the plurality of components to identify good components and bad components, wherein good components are those components which successfully pass testing and bad components are those components which fail testing; defining a first good components to be picked from the carrier; defining an integer number of components to be a jump value; locating a pickup head, which is operable to pick components from the carrier, above a first reference position on the carrier; identifying one or more good components, which are within the jump value from the first reference position; moving the pickup head or the carrier so that the pickup head is centered above at least one of the one or more good components; moving the pickup head or the carrier, so that the pickup head is moved from above said at least one of the one or more good components to above the defined first good component to be picked without picking said at least one of the one or more good components; centering the pickup head above the first good components to be picked; picking the first good components to be picked.

Preferably the carrier is a wafer.

Preferably the components are dies.

Advantageously moving the pickup head so that it is centered above at least one of the one or more good components implements an intermediate alignment of the pickup head; thus as the pickup head is being moved from the first reference position on the carrier to the first die to be picked, the pickup head undergoes at least one alignment with respect to a component on the carrier before it reaches the first component to be picked. The alignment which the pickup head undergoes decreases the possibility for the pickup head to be centered above a device which is not the defined first device to be picked, and thus decreases the possibility of the pickup head to incorrectly pick a component which is not the defined first device to be picked, due to the accumulation of position errors of components on the carrier.

The step of defining an integer number of components to be a jump value may comprise, defining an integer number of components greater than ‘1’ to be a jump value.

The method may comprise identifying a plurality of good components, which are within the jump value from the first reference position. The method may comprise moving the pickup head so that it is consecutively centered above at least two good components, before moving the pickup head to above the defined first good component to be picked without having picked any of said at least two good components.

The method may comprise identifying all of good components, which are within the jump value from the first reference position, and the method may further comprise the steps of, determining a path, between the first reference position and the first good component to be picked, which requires the pickup head to undergo the least number of jumps in order to move from the first reference position to the first good component to be picked, wherein a jump comprises moving the pickup head over an number of components less than or equal to the jump value, and centering the pickup head above a component. The method may comprise the steps of moving the pickup head so that it is centered above one or more good components which are position on said determined path which requires the pickup head to undergo the least number of jumps, before moving the pickup head to above the defined first good component to be picked.

The method may comprise identifying all of good components, which are within the jump value from the first reference position, and the method may further comprise the steps of, determining a path which has the shortest distance, between the first reference position and the first good component to be picked. The method may further comprise the steps of moving the pickup head so that it is centered above one or more good components which are positioned on said determined path, before moving the pickup head to above the defined first good component to be picked.

The method may comprise the steps of, (a) determining a score (F) for each good component which is within the jump value from the first reference position, by, for each good component, adding a cost value (G) which is representative of the cost of moving the pickup head from its first reference position to said component, plus a cost value (H) which is representative of the estimated cost to move from said component to the first component which is to be picked; (b) moving the pickup head so that it is centered above the component which has the lowest (F) score; (c) if the component which has the lowest score is within the jump value from the first component to be picked, then moving the pickup head from the component which has the lowest score to the first component to be picked; if the component which has the lowest score is not within the jump value from the first component to be picked, then determining a score (F) for each good component which is within the jump value from said component, by, for each good component, adding a cost value (G) which is representative of the cost of moving the pickup head from its current position to said component, plus a cost value (H) which is representative of the estimated cost to move from said component to the first component which is to be picked, and moving the pickup head so that it is centered above the component which has the lowest score (F), repeating these steps until the pickup head is centred above a component which is within the jump value from the first component to be picked.

The method may further comprise the steps of, (a) identifying one or more good components, which are within the jump value from the current position of the pickup head; (b) moving the pickup head so that it is centered above at least one of the identified one or more good components; (c) moving the pickup head from above said at least one of the one or more good components to above another good component to be picked without picking said at least one of the one or more good components; (d) centering the pickup head above said other good component to be picked; (e) picking said other good component to be picked; (f) repeating the steps a-e until a predefined number of components have been picked from the carrier.

For example the method may comprises the steps of, identifying one or more good components, which are within the jump value of the position which was occupied by the first good component to be picked; moving the pickup head so that it is centered above at least one of the identified one or more good components; moving the pickup head from above said at least one of the one or more good components to above a second good component to be picked without picking said at least one of the one or more good components; centering the pickup head above the second good component to be picked; picking the second good component to be picked.

The method may further comprise the step of, generating a map file having data which represents the positions of the good components and the positions of bad components on the carrier, and wherein the map file for a respective carrier is generated prior to picking any components from that carrier. The method may comprise using the map file to, identify one or more good components which are within the jump value of the first reference position, and/or identify one or more good components which are within the jump value of a component over which the pickup head is centered.

In one embodiment said first reference position on the carrier is a defined by a fiducial defined on the carrier, and/or is defined by a predefined component on the carrier.

The step of moving the pickup head so that it is centered above a component may comprise, using a vision system to view the positioning of the pickup head with respect to that component.

According to a further aspect of the present invention there is provided a component handling apparatus, comprising, a pickup head which is operable to pick components from a carrier; and a data processing means which is programed to implement the method according to any one of the above-mentioned methods.

### BRIEF DESCRIPTION OF THE DRAWINGS

The invention will be better understood with the aid of the description of an embodiment given by way of example and illustrated by the figures, in which:

FIG. 1 is a flow chart of the steps involved in a method according to one embodiment of the present invention;

FIG. 2a-h illustrates, schematically, the performance of the steps of the method shown in FIG. 1;

FIGS. 3a-e illustrates, schematically, the performance of the steps of the method according to a further embodiment of the present invention;

FIG. 4 illustrates a plan view of wafer having a plurality of good dies and bad dies, and shows the first good die to be picked and the pickup head aligned over a first reference die on the wafer;

FIG. 5 illustrates a plan view of wafer of FIG. 4 with the score (F) and cost values ((G)&(H)) shown for each die which is within a jump value number of dies from a first reference die.

### DETAILED DESCRIPTION OF POSSIBLE EMBODIMENTS OF THE INVENTION

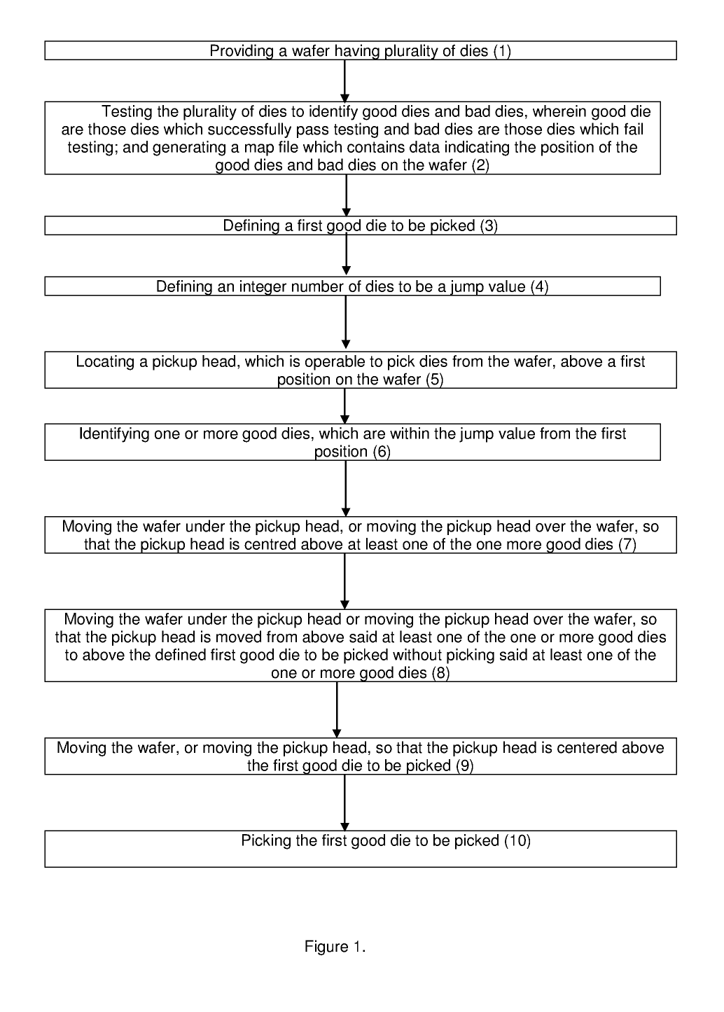

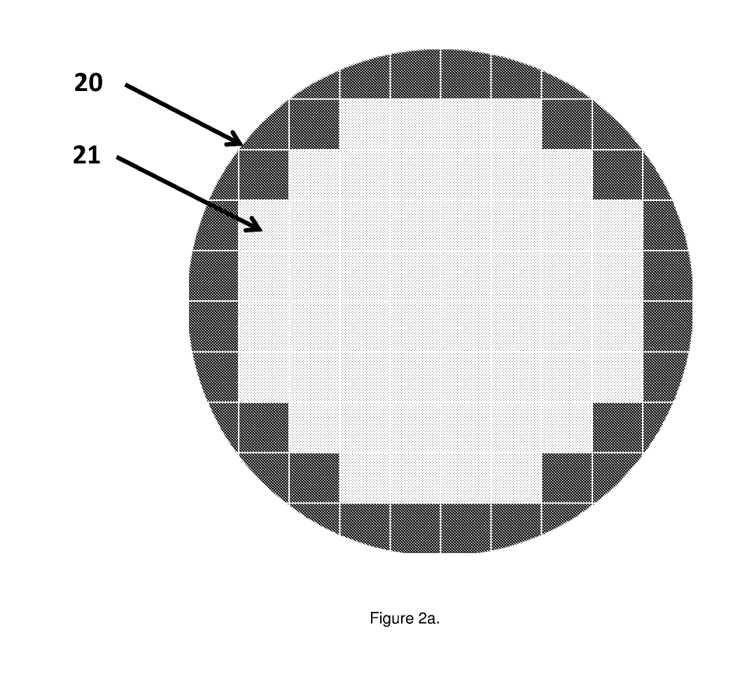

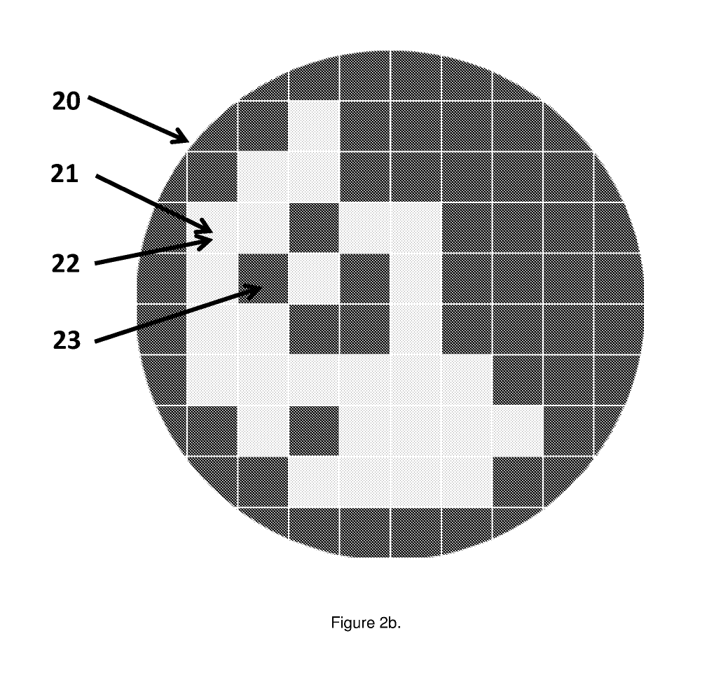

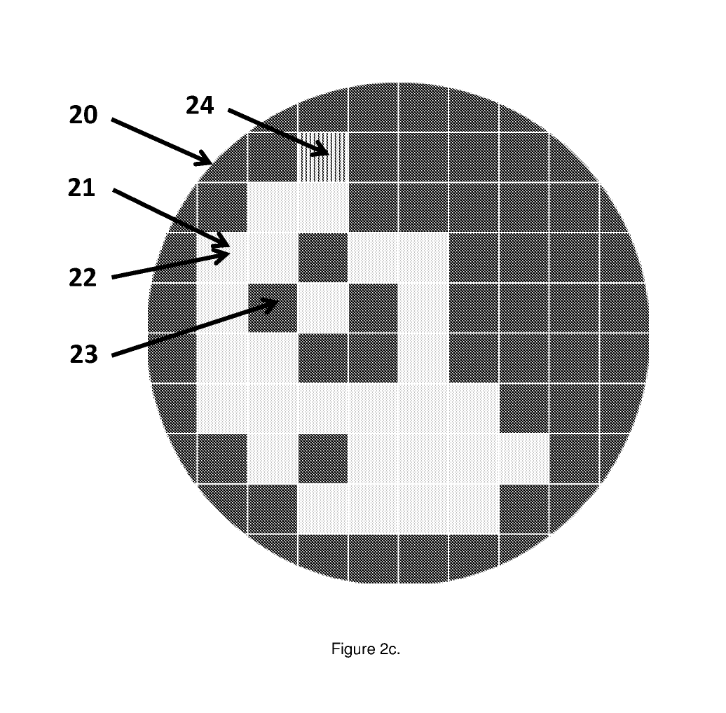

FIG. 1 is a flow chart detailing the steps which are involved in a method of handling components (which are dies in this example) on a carrier (which is in the form of a wafer in this example) according to an embodiment of the present invention. The flow chart includes the steps of providing a wafer having a plurality of dies thereon 1. It should be understood that the present invention is not limited to use with wafers and that the dies maybe provided any suitable carrier (e.g. Silicon wafer or carrier tray or any carrier device). Also the present invention is not limited to use with dies, and that the present invention can be used to handle any suitable components (e.g. Silicon dies or molded semiconductor packages or any units that can be conditioned on wafer foil or on a Silicon wafer or carrier tray or any carrier device).

The plurality of dies are then tested to identify good dies and bad dies, wherein good die are those dies which successfully pass testing and bad dies are those dies which fail testing; and a map file which contains data indicating the position of the good dies and bad dies on the wafer is generated 2. The type of testing which the dies undergo is not essential to the present invention; the dies may undergo any suitable testing; preferably all of the dies on the wafer undergo the same testing, and those which pass the testing are designated as being ‘good’ dies and those which fail the testing are designated as ‘bad’ dies. In the preferred embodiment of the present invention the dies have been tested to identify good dies and bad dies, a map file is generated; the map file will contain data indicating the location of each good die and bad die on the wafer. For example the map file may comprise a series of coordinates (e.g. x-y coordinates), each coordinate corresponding to the position of a respective die on the wafer, and the map file may also contain data indicating if the die corresponding to a respective coordinate is a good die or a bad die, and/or data indicating the number of good dies and/or the number of bad dies on the wafer. Advantageously, in the present embodiment the locations of each of the good die and bad die on the wafer is determined before the pickup head picks any die from the wafer.

A first good die to be picked is then defined 3. The first good die to be picked may be defined simply by a user selecting the first good die to be picked. In another embodiment the map file suggests one or more dies to be the first die to be picked and one of those dies suggested in the map file is selected to be the first die to be picked.

An integer number of dies to be a jump value is then defined 4 (the jump value defines the maximum number of dies on the wafer over which the pickup head can jump/move when moving from one die to another; in one embodiment the pickup head is stationary and the wafer can be moved with respect to the pickup head so that the pickup head jumps over dies on the wafer; in another embodiment the wafer is stationary and the pickup head itself is moved to jump over dies on the wafer).

A pickup head, which is operable to pick dies from the wafer, is subsequently located above a first reference position on the wafer 5. In this example the first reference position is a position which is different to the position of the defined first good die to be picked. One or more good dies, which are within the jump value from the first reference position are then identified 6.

The wafer is then moved so that one of the one or more good diesis centered below the pickup head 7. In a variation of this embodiment the pickup head is moved so that it is centered above at least one of the one or more good dies. In this invention a vision/camera system may be used to facilitate the centering of the pickup head with respect to a good die.

The wafer is then moved so that the defined first good die to be picked is centered under the pickup head, without having picked said one of the one or more good dies which was centered under the pickup head 8. In a variation of this embodiment pickup head is moved from above said one of the one or more good dies to above the defined first good die to be picked without having picked said one of the one or more good dies.

The wafer is then moved so that the first good die to be picked 9 is centered under the pickup head. In a variation of this embodiment the pickup head is moved so that it is centered above the first good die to be picked 9. The first good die to be picked is then picked by the pickup head 10.

Advantageously moving the wafer (or pickup head) so that the pickup head is centered above at least one of the one or more good dies, implements an intermediate alignment of the pickup head before the predefined first die to be picked is centered under the pickup head. Thus as wafer (or pickup head) is moved so that the pickup head is centered above a first reference position on the wafer to the first die to be picked, the pickup head undergoes at least one alignment with respect to an intermediate good die on the wafer before it reaches the first die to be picked. The centering/alignment of the pickup head under the intermediate good die decreases the possibility for the pickup head to incorrectly pick a die which is not the defined first device to be picked, due to the accumulation of position errors of dies on the wafer.

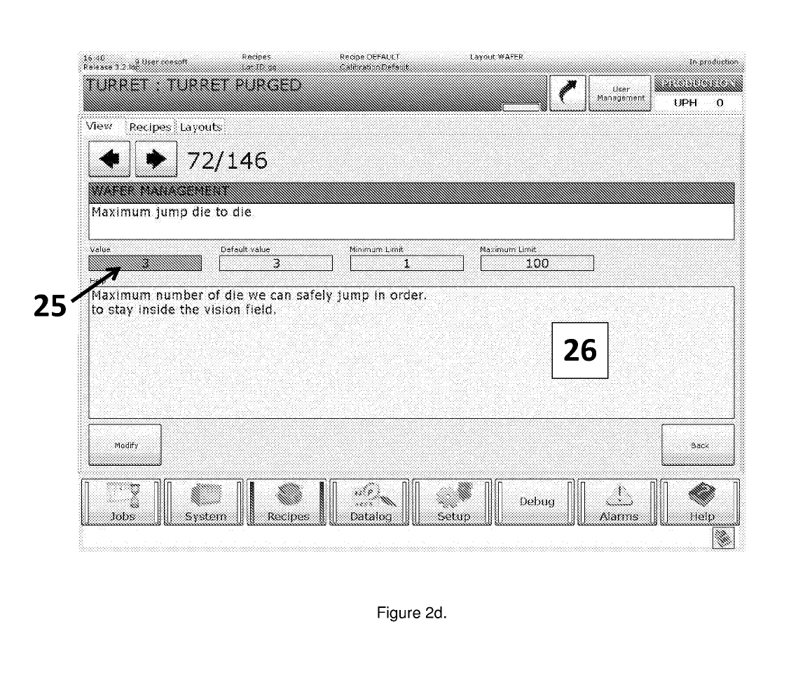

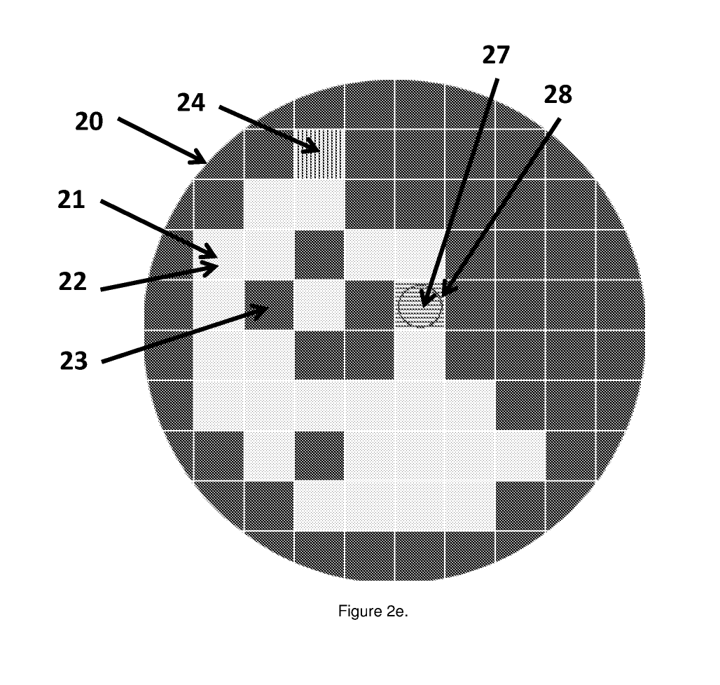

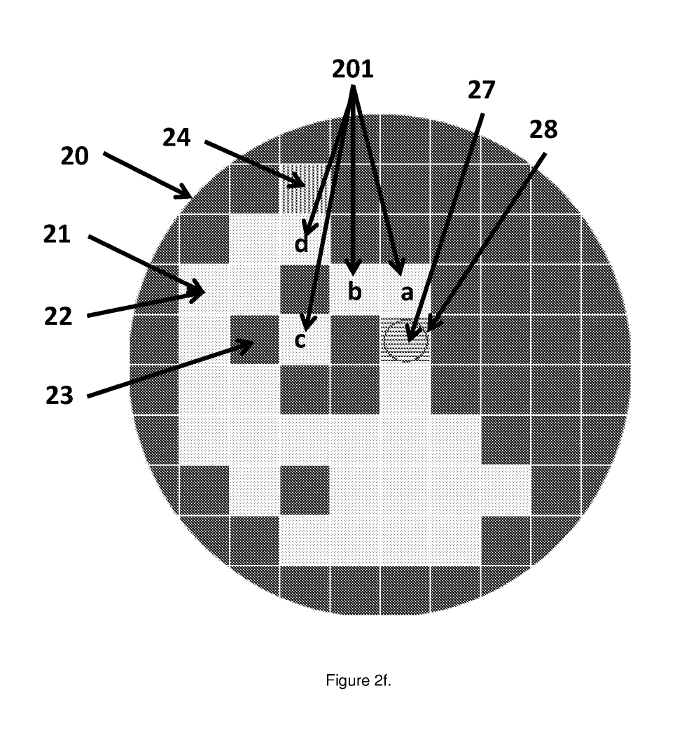

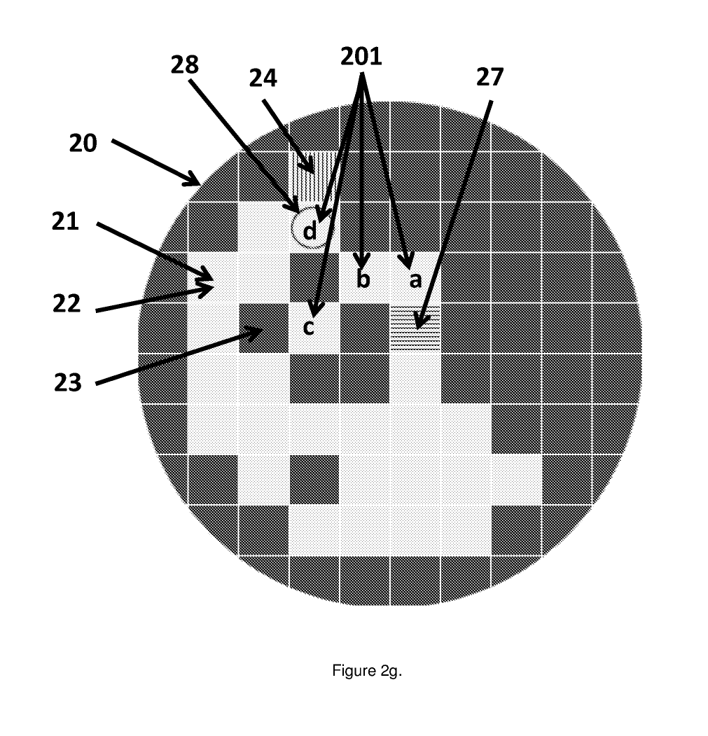

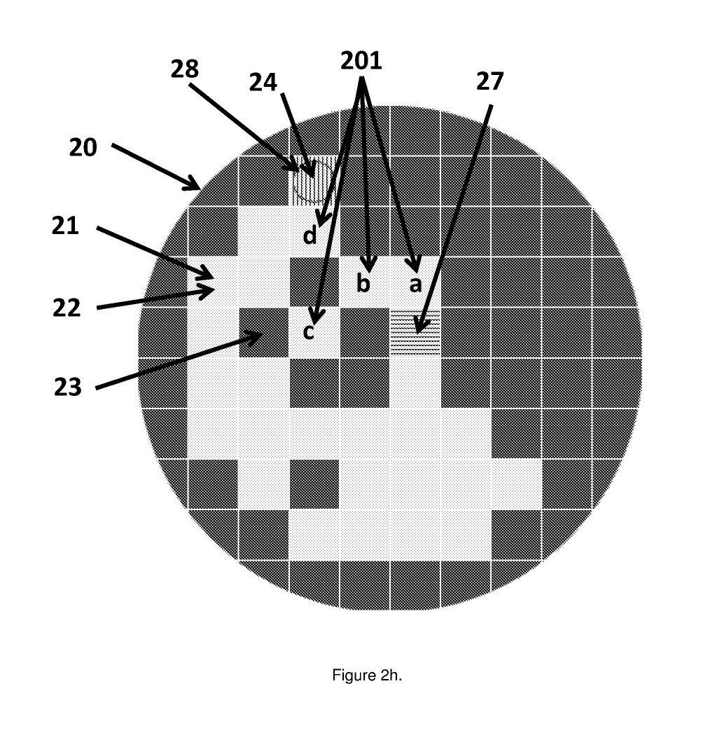

FIG. 2a-h illustrates the steps of a method according to one embodiment of the present invention. FIG. 2a shows a wafer 20, which has been provided, having a plurality of dies 21 thereon.

The plurality of dies 21 are then tested to identify good dies and bad dies, wherein good dies are those dies which successfully pass testing and bad dies are those dies which fail testing. It should be understood that the dies could be subjected to any type of testing to determine if they are good or bad dies. In this example each of the dies 21 have undergone electrical testing to determine if the electrics of each die are functioning correctly. Those dies whose electrics are functioning correctly are considered to be good dies, and those dies whose electrics are flawed are considered to be bad dies. FIG. 2b shows good dies 22 as grey boxes and the bad dies 23 as black boxes.

In this embodiment a map file having data which represents the positions of the good dies 22 and position of bad dies 23 on the wafer 20 is then generated. For example, the map file may comprise a series of coordinates (e.g. x-y coordinates), each coordinate corresponding to the position of a respective die on the wafer, and the map file may also contain data indicating if the die corresponding to a respective coordinate is a good die or a bad die, and/or data indicating the number of good dies and/or the number of bad dies on the wafer. The map file may also be used to determine the location of a fiducial/reference on the wafer, as well as being used to determine non-authorized areas on the wafer (e.g. to determine areas on the wafer which are occupied by fiducial device(s); areas on the wafer where there is no die present (e.g. where dies have already been picked (partial wafers)); areas on the wafer which are occupied by none-active devices (mirror areas)). In any case, these non-authorized areas on the wafer are areas which the pickup head should preferably avoid and the map file contains data which identifies those non-authorized areas or data which can be used to determine such non-authorized areas.

A first good die 24 to be picked is then defined. In one embodiment a user will define/select the first good die 24 to be picked. The present invention provides to more reliably move the pickup head precisely to the defined first good die 24 to be picked without requiring user intervention. FIG. 2c shows a first good die 24 (striped box) to be picked, as selected by the user. In one embodiment potential first good dies 24 to be picked may be suggested in the map file; in such a case the present invention may involve selecting the first good die to be picked from the potential first good dies 24 that are suggested in the map file; for example out of the potential first good dies 24 to be picked which are suggested in the map file, the good die which will enable to perform the most efficient picking of all of the good dies on the wafer may be selected to define the first good die 24 to be picked.

An integer number of dies to be a ‘jump value’ is then defined. The user may arbitrarily choose an integer number of dies to be the jump value. In the present application the ‘jump value’ is the maximum number of dies over which a pick head can move over, without requiring the pickup head to be centered with respect to a die. It should be understood that in the present invention centering the pickup head with respect to a die can be achieved either by moving the wafer so that the die is centered under the pickup head, or moving the pickup head so that the pickup head is centered over the die. Typically if accurate alignment of the pickup head over the dies on the wafer is a priority over speed of picking (i.e. if the accuracy of picking is prioritized over speed of picking) then the user will choose a low integer to be the jump value (e.g. an integer between 1-6; preferably an integer between 2-6); if on the other hand the user prioritizes speed of picking the dies from the wafer over accuracy of picking, then the user will choose a high integer to be the jump value (e.g. a integer between 7-12).

FIG. 2d provide a screen shot of a software user interface 25, for a software which implements the method; it can be seen software user interface 25 provides a field 26 in which the user can select an integer (1-12) for the jump value. In this example the user has selected an integer ‘3’ to be the jump value; this means that the pickup head is allowed to jump over a maximum of ‘3’ dies on the wafer 20 at any one time. In other words each movement of the wafer or pickup head is restricted so that the pickup head can jump over a maximum of ‘3’ dies on the wafer 20 at any one time. Of course it should be understood that the wafer or pickup head can be moved so that the pickup head jumps over a less than ‘3’ dies. Likewise if the user has selected an integer ‘6’ to be the jump value, then the pickup head could jump over a maximum of ‘6’ dies on the wafer 20.

A pickup head, which is operable to pick dies 21 from the wafer 20, is subsequently located above a first reference position on the wafer 20. FIG. 2e shows a pickup head 28 which has been located above a first reference position on the wafer 20; in this example the first reference position is defined to be above a first reference die 27 which is positioned at the edge of the wafer 20. However it will be understood that the pickup head 28 could alternatively have been located at any another position which has been predefined as the first reference position; for example the wafer 20 may have fiducials or makings provided thereon which define the first reference position on the wafer above which the pickup head 28 is to be located.

The one or more good dies 22, which are within the jump value from the first reference position are then identified. In the preferred embodiment one or more good dies 22, which are within the jump value from the first reference position are then identified from the map file which contains data indicating the location of each good die and bad die on the wafer. In this example the jump value is ‘3’; accordingly the software identifies one or more good dies 22 which are within ‘3’ dies from the first reference die 27. As shown in FIG. 2f there are four good dies 201a-d which are within ‘3’ dies from the first reference die 27. The good die 201a is ‘1’ die from the first reference die 27 and the good die 201b is ‘1.4’ dies from the first reference die 27 (i.e. ‘1’ die along an one axis (e.g. x.axis) and ‘1’ die along another orthogonal axis (e.g. y-axis), which gives by pythagoras theorem, ‘square root of (1²+1²))’=1.4 die); good die 201c is less than ‘3’ dies away from the first reference die 27 (i.e. is ‘2’ dies away); and good die 201d is also less than ‘3’ dies away from the first reference die 27 (i.e. is ‘2.828’ dies away by pythagoras theorem).

The wafer 20 is moved (or the pickup head is moved) so that the pickup head is centered above one of the good dies 201a-d. In this example the good die which is positioned closest to the first good die 24 to be picked is identified; and the wafer 20 is then moved (or the pickup head is then moved) so that the pickup head is centered above the good die which is positioned closest to the first good die 24 to be picked. Thus, as shown in FIG. 2g, in this example the wafer 20 is moved (or the pickup head is moved) so that the pickup head is centered above the good die 201d, since the good die 201d is closest to the first good die 24 to be picked. Importantly the pickup head does not pickup the good die 201d, rather the pickup head is only centered above the good die 201d.

Since the first good die 24 to be picked is located within ‘3’ dies of the good die 201d, after the pickup head 28 has been aligned with the good die 201d, the pickup head 28 is then be moved from above said good die 201d to above the first good die 24 to be picked, as shown in FIG. 2h. The wafer 20 (or pickup head) is moved so that the pickup head is centered above the first good die 24 to be picked; and the first good die 24 to be picked is then picked by the pickup head.

Thus the wafer 20 is moved (or the pickup head is moved), stepwise, so that pickup head is moved from the first reference die 27 towards the first good die 24 to be picked. The pickup head is centered with respect to the intermediate good die 201b before being moved to pick the defined first good die 24 to be picked. The jump value defines the maximum number of dies over which a pickup head can jump, when taking a step from one die to another. As the wafer 20 (or pickup head) is moved so that the pickup head is moved, stepwise, from the first reference die 27 towards the first good die 24 to be picked, the wafer 20 (or pickup head) is moved so that the pickup head is centered over an intermediate good die 201d; advantageously this ensures more reliable centering of the pickup head above the defined first good die 24 to be picked since the accumulation of position errors of dies between intermediate good die 201d and the first good die 24 to be picked is less than the accumulation of position errors of dies between the first reference die 27 and the first good die 24 to be picked.

Referring again to FIG. 2f it can be seen that there are four different good dies 201a-d all which are within ‘3’ dies from the first reference die 27. In the example given the wafer 20 (or pickup head) is moved so that the pickup head is centered above the good die 201d, since this is positioned closest to the first good die 24 to be picked.

In some scenarios there is good die 22 within the jump value from the die which closest to the first good die 24 to be picked, however this good die 22 may be rejected (e.g. because an image taken by the vision system shows that the die is faulty or displaced); and in that particular case, the wafer 20 (or pickup head) is moved so that the pickup head is centered over a different good die 22.

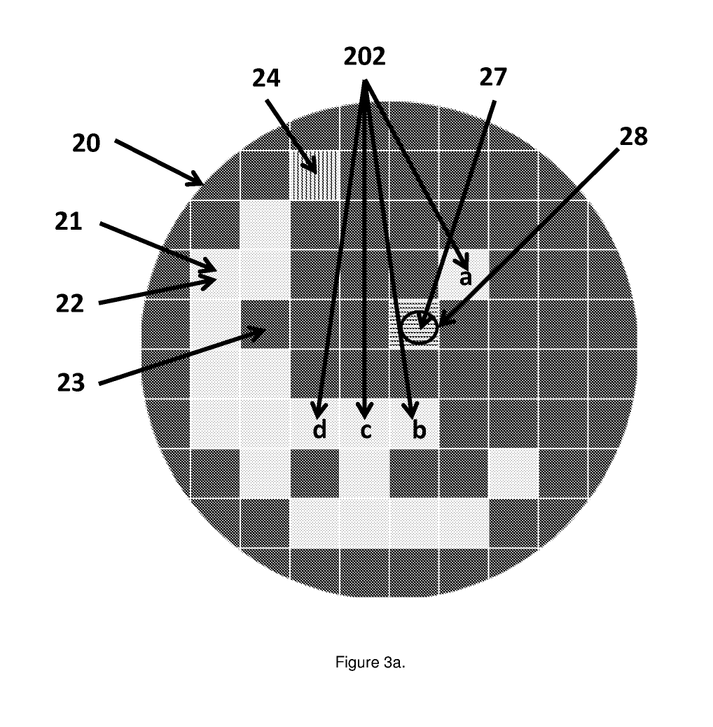

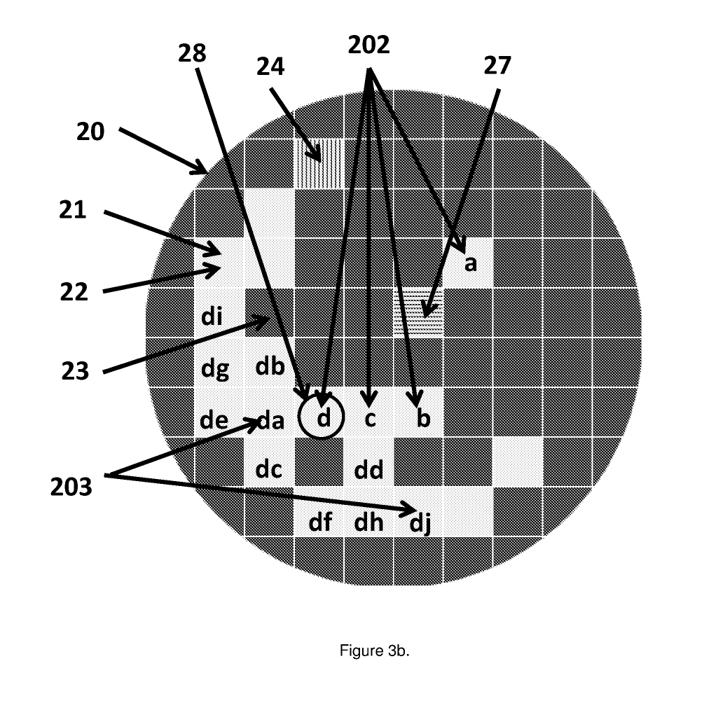

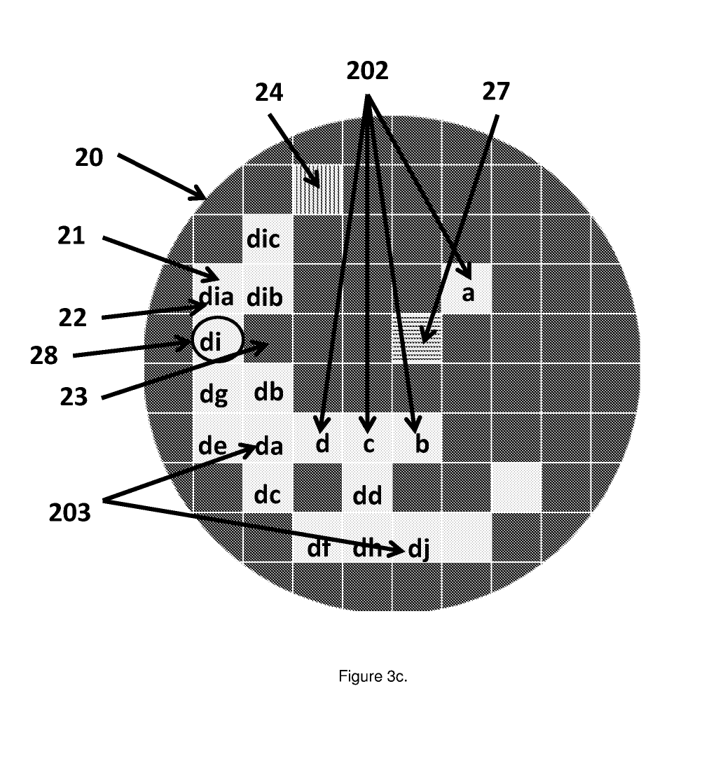

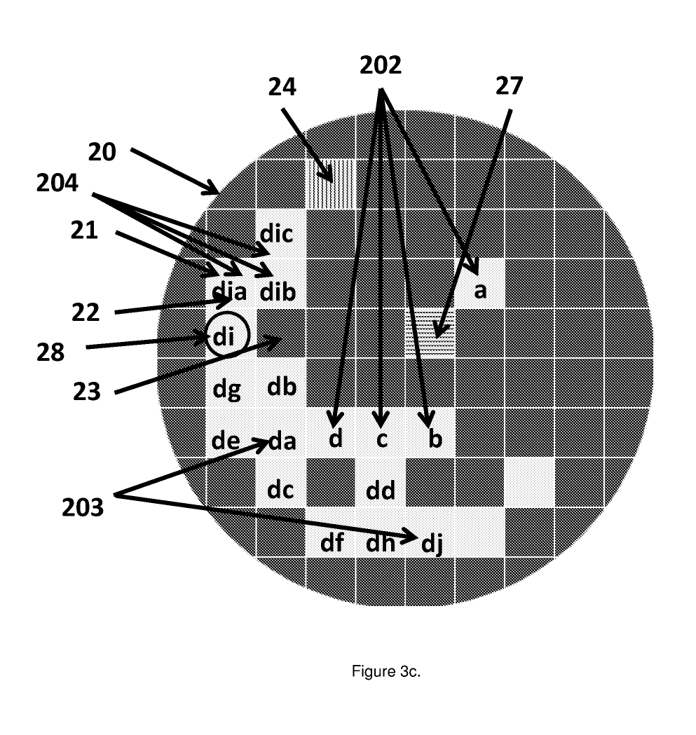

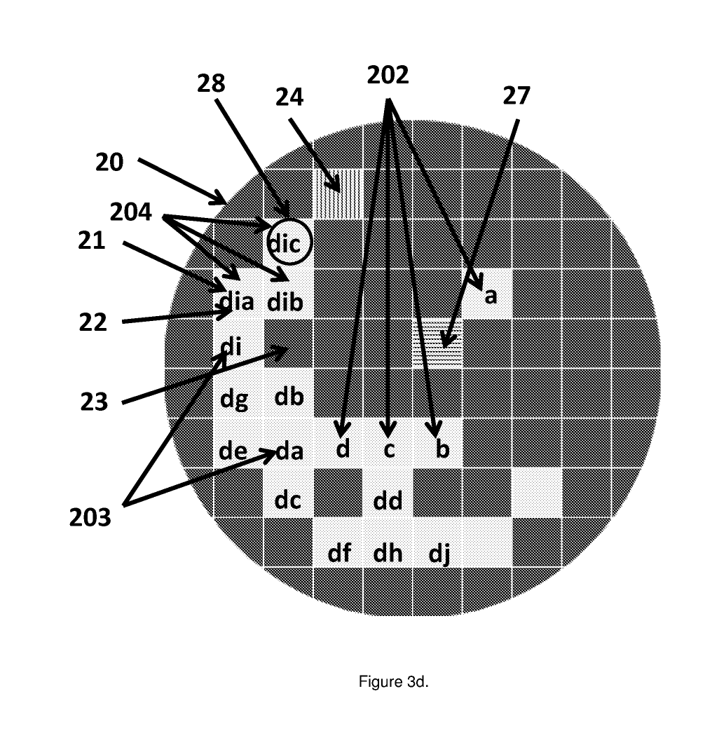

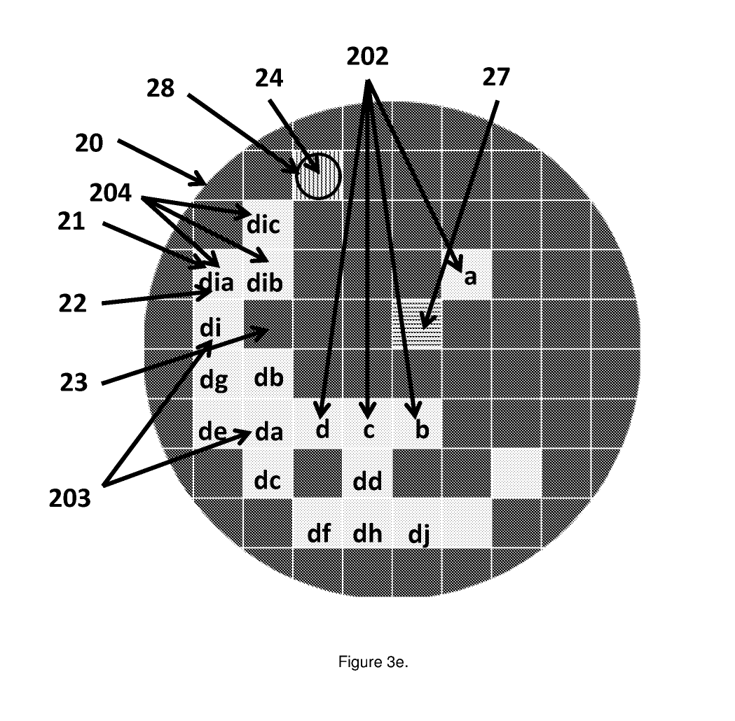

In some other scenarios there is no good die within the jump value from the die which closest to the first good die 24 to be picked; accordingly a different path must be taken as shown in FIGS. 3a-d.

FIG. 3a illustrates a stage in the method corresponding to the stage illustrated in FIG. 2f and shows good dies 22 as grey boxes and the bad dies 23 as black boxes. The first good die 24 to be picked is illustrated with vertical stripes. The jump value is defined to be ‘3’ in this example; and similar to FIG. 2f there are four good dies 202a-d which are within ‘3’ dies from the first reference die 27, with the good die 202a being in a position which is closest to the first good die 24 to be picked.

However if the wafer 20 (or pickup head 28) were to be moved so that the pickup head 20 is centered above the good die 202a, then the pickup head could not subsequently be moved any further since all dies which are within the ‘3’ dies (i.e. the jump value) of the good die 202a are bad dies. Consequently the pickup head could not reach the first good die 24 to be picked.

Accordingly in another embodiment of the present invention the method involves the step of checking if the good die which is closest to the first good die 24 to be picked, has other good dies which are within the jump value away. If the good die which is closest to the first good die 24 to be picked, does not have other good dies which are within the jump value away from said good die, then the method involves checking if the good die which is second closest to the first good die 24 to be picked, has other good dies which are within the jump value away. If the good die which is second closest to the first good die 24 to be picked, does not have other good dies which are within the jump value away, then the method involves checking if the good die which is third closest to the first good die 24 to be picked, has other good dies which are within the jump value away etc. Thus in this embodiment the good die which is closest to the first good die 24 to be picked and which also has other good dies which are within the jump value away (or has the first good die 24 to be picked within the jump value away) is identified; and the pickup head is then centered over this identified good die.

In the example illustrated in FIG. 3b the pickup head 28 is centred over the good die 202d (i.e. the wafer 20 has been moved so that the pickup head 28 is centred over the good die 202d; or the pickup head 28 is moved to be centred over the good die 202d), since this good die 202d is the closest good die to the first good die 24 to be picked which has other good dies 22 which are within the jump value (‘3’ dies) away.

Next, good dies 22, which are within the jump value (i.e. with ‘3’ dies) from the good die 202d are then identified 203da-dj. In this example the jump value is ‘3’, accordingly the software identifies one or more good dies which are within ‘3’ dies from the good die 202d (except those good dies which are within a jump value from the good die over which the pickup head was last centered (i.e. which in this case all those good dies which are within 3 dies of the first reference die 27). As shown in FIG. 3b there are ten good dies 203da-dj within ‘3’ dies from the good die 202d (excluding those good dies which are within 3 dies of the first reference die 27 i.e. excluding the four good dies 202a-d). In this particular embodiment those good dies which were within the jump value of the good die over which the pickup head was last centered, are not considered i.e. the pickup head was last centered over the first reference die 27 and the four good dies 202a-d were within the jump value (‘3’ dies) from the first reference die 27; thus the four good dies 202a-d are not considered as being good dies 22 which are within the jump value (i.e. with ‘3’ dies) from the good die 202d. In the present invention this is the case when determining the good dies which are within the jump valve of a die: all those dies which are within the jump value of the die are considered, except for those good dies which are within the jump value of the good die over which the pickup head was last centered.

As shown in FIG. 3c the wafer 20 (or pickup head 28) is then moved so that the pickup head 28 is centered above one of the ten good dies 203da-dj. Out of the ten good dies 203da-dj the good die which is positioned closest to the first good die 24 to be picked is identified; and the wafer 20 (or pickup head 28) is then moved so that the pickup head 28 is centered above the good die which is positioned closest to the first good die 24 to be picked. In this example the good die 203di is the good die which is positioned closest to the first good die 24 to be picked. The wafer 20 (or pickup head 28) is moved so that the pickup head 28 is centered above the good die 203di, since this is positioned closest to the first good die 24 to be picked. Importantly the pickup head 28 does not pick up the good die 203di at this stage, rather the pickup head is only centered above the good die 203di.

As illustrated n FIG. 3d, next good dies 22 which are within the jump value (i.e. with ‘3’ dies) from the good die 203di (and are not within the jump value of the good die over which the pickup head was last centered) are identified 204dia-dic. Out of the three good dies 204dia-dic the good die 204dic which is positioned closest to the first good die 24 to be picked is identified; and the wafer 20 (or pickup head 28) is then moved so that the pickup head 28 is centered above the good die 204dic which is positioned closest to the first good die 24 to be picked. Importantly the pickup head 28 does not pickup either of the good dies 203di and 20dic at this stage, rather the pickup head 28 is only centered consecutively above the good dies 203di and 20dic.

As shown in FIG. 3e, since the first good die 24 to be picked is located within the jump value (i.e within ‘3’ dies) from the good die 204dic, the pickup head 28 can then be moved directly from above said good die 204dic to above the first good die 24 to be picked (or the wafer 20 can be moved so that the pickup head 28 is above the first good die 24 to be picked). The wafer 20 (or pickup head 28) is moved so that the pickup head 28 is centered above the first good die 24 to be picked; and the first good die 24 to be picked is then picked by the pickup head.

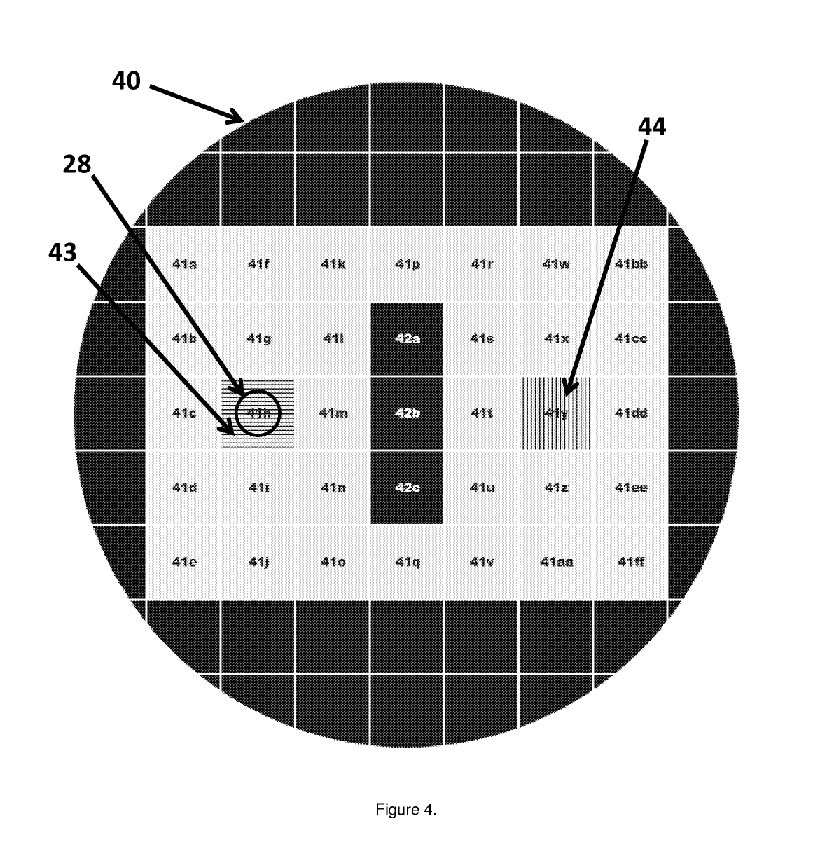

FIG. 4 shows a wafer 40, which has been provided, having a plurality of dies 21 thereon. The plurality of dies 21 have already been tested to identify good dies 41a-ff and bad dies 42a-c. FIG. 4 shows good dies 41a-ff as grey boxes and the bad dies 42a-c as black boxes.

The first good die to be picked 44 (vertical striped box) has been defined; and an integer number of ‘3’ dies has been defined for the jump value (this means that the pickup head can jump over a maximum of ‘3’ dies on the wafer 40 at any one time—in one embodiment the pickup head is stationary and the wafer can be moved with respect to the pickup head so that the pickup head jumps over dies on the wafer; in another embodiment the wafer is stationary and the pickup head itself is moved to jump over dies on the wafer). It will be understood that the jump value may be any integer number.

A pickup head 28, which is operable to pick dies 21 from the wafer 20, is located above a first reference position 43 on the wafer 40, which in this example is above a first reference die 43 (horizontal striped box). However it will be understood that the pickup head 28 could alternatively have been located at any another position which has been predefined as the first reference position; for example the wafer 40 may have fiducials or markings provided thereon which define the first reference position on the wafer above which the pickup head 28 is to be located.

All of the good dies 41a-q and 41t which are within the jump value from the first reference die 43 are then identified. In this example the jump value is ‘3’, accordingly all of the good dies 41a-q and t, which are within ‘3’ dies of the first reference die 43 are then identified. Dies 42a-c are within the within ‘3’ dies of the first reference die 43 but are not good dies; good dies 41r,s,u-z, and 41aa-ff are good dies but are more than ‘3’ dies away from the first reference die 43 (e.g. good die 41r is a distance ‘3.6’ dies away from the first reference die 43 i.e. the good die 41r is ‘3’ dies along the horizontal, and ‘2’ along the vertical away from the first reference die 43 and thus is a distance ‘sqr(3²+2²)’ from the first reference die 43); good dies 41a-q, and 41t are within ‘3’ dies of the first reference die 43 (e.g. the good die 41t is ‘3’ dies away from the first reference die 43 and good die 41p is ‘2.8’ dies away from the first reference die 43).

Importantly the first good die 44 to be picked is not within the jump value from the first reference die 43; the first good die 44 to be picked is more than ‘3’ dies away from the first reference die 43. Since the first good die 44 to be picked is not within ‘3’ dies of the first reference die 43, the pickup head 28 cannot jump directly from the first reference die 43 to the first good die 44 to be picked. Therefore, in order to get to the first good die 44 to be picked from the first reference die 43 the wafer 20 (or pickup head 28) is move so that a first intermediate good die, which is within the jump value (‘3’ dies) of the first good die 44 to be picked, is centered under the pickup head 28; if that first intermediate good die is within the jump value (‘3’ dies) of the first good die 44 to be picked then the wafer 20 (or pickup head) can then be moved so that the pickup head is moved directly from that first intermediate good die to be centered above the first good die 44 to be picked; if however the first intermediate good die is not within the jump value (‘3’ dies) of the first good die 44 to be picked then the wafer 20 (or pickup head 28) is moved so that the pickup head is moved from the first intermediate good die to be centered above a second intermediate good die, and subsequently is moved to be centered above other intermediate good dies if necessary, until the pickup head eventually reaches (i.e. is centered above) an intermediate good die which is within the jump value (‘3’ dies) of the first good die 44 to be picked; the pickup head then jumps from that intermediate good die which is within the jump value (‘3’ dies) of the first good die 44 to be picked to the first good die 44 to be picked.

In the example show in FIG. 4 it can be seen that there are a plurality of good dies 41a-q, 41t, all which are within ‘3’ dies of the first reference die 43; accordingly there are a plurality of different paths that the pickup head could follow in order to get from the first reference die 43 to the first good die 44 to be picked: for example in one possible path the pickup head could jump from the first reference die 43 to die 41k, from the die 41k to die 41r and then from die 41r to the first die to be picked 44, because die 41k is within the jump value (‘3’ dies) of the first reference die 43, die 41r is within the jump value (‘3’ dies) of the die 41k, and the first die to be picked 44 is within the jump value (‘3’ dies) of 41k. In a second possible path the pickup head could jump from the first reference die 43 to die 41m, from the die 41m to die 41t and then from die 41t to the first die to be picked 44, because die 41m is within the jump value (‘3’ dies) of the first reference die 43, die 41r is within the jump value (‘3’ dies) of the die 41k, and the first die to be picked 44 is within the jump value (‘3’ dies) of 41k. In a third possible path the pickup head could jump from the first reference die 43 to die 41t, from the die 41t to the first die to be picked 44, because die 41t is within the jump value (‘3’ dies) of the first reference die 43, and the first die to be picked 44 is only ‘1’ die away from the die 41t and therefore is within the jump value (i.e. is within ‘3’ dies from die 41t) from die 41t. Above are mentioned three possible exemplary paths, however there are numerous other possible paths which the pickup head could take to move from the first reference die 43 to the first die to be picked 44.

In the present application it will be understood that in the present invention the term ‘jumping’ to a die means to move the wafer or pickup head so that the pickup head is above the die, and subsequently moving the wafer or pickup head so that the pickup head is centered over that die. It should be understood that a vision or camera system may be used to facilitate moving the wafer or pickup head so that the pickup head is centered over that die. Centering the pick-up head over a die is time consuming, therefore in order to move the pickup head from the first reference die 43 to the first die to be picked 44 as quickly as possible the path which requires the least number of jumps is preferably taken. In the example shown in FIG. 4a the path with the least number of jumps is the path in which the pickup head jumps from the first reference die 43 to the die 41t and jumps from the die 41t to the first die to be picked 44 (i.e. the third possible path mentioned in the example above); this path requires only two jumps in order for the pickup head to move from the first reference die 43 to the first die to be picked 44. The second and third possible paths described above each require three jumps for example and thus it would take the pickup head longer to move from the first reference die 43 to the first die to be picked 44 if either of these paths were taken.

It should be noted that there may be more than one path which have the same least number of jumps. For example, the path in which the pickup head jumps from the first reference die 43 to the die 41m and jumps from the die 41m to the first die to be picked 44, also only requires two jumps. Likewise, the path in which the pickup head jumps from the first reference die 43 to the die 41p and jumps from the die 41p to the first die to be picked 44, also only requires two jumps; and the path in which the pickup head jumps from the first reference die 43 to the die 41q and jumps from the die 41q to the first die to be picked 44, also only requires two jumps. However in the example shown in FIG. 4, when the jump value is ‘3’, the is no path along which the pickup head could move to get from the first reference die 43 to the first die to be picked 44, which requires less than ‘2’ jumps. In the present invention any path which has the least number of jumps may be taken; thus any of the exemplary paths mentioned above which require only ‘2’ jumps may be taken.

In a further embodiment the present invention the path which requires the least number of jumps, and which also has the least physical distance is selected. In the example shown in FIG. 4 it was seen that many paths which had the least number of jumps i.e. there were many paths which required that the pickup head to undergo only two jumps; however in this further embodiment the path which requires the pickup head to move the least physical distance to get from the first reference die 43 to the first die to be picked 44 is selected (i.e. the path which is the least physical distance between the first reference die 43 to the first die to be picked 44). In FIG. 4 the path that requires the least number of jumps, and which also has the least physical distance, is the path in which the pickup head jumps from the first reference die 43 to the die 41t and jumps from the die 41t to the first die to be picked 44 (or the path in which the pickup head jumps from the first reference die 43 to the die 41m and jumps from the die 41m to the first die to be picked 44 both paths require the same number of jumps and require the pickup head to move the same physical distance); the other paths mentioned above would require the pickup head to move over a greater physical distance.

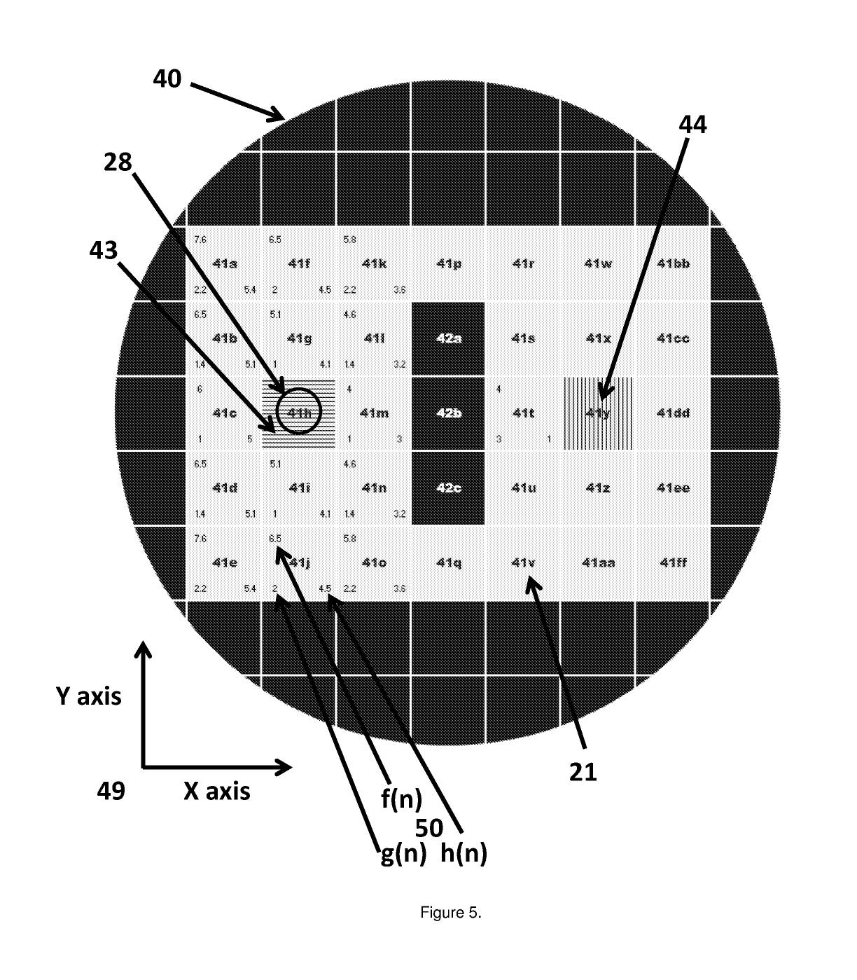

FIG. 5 illustrates an example of how the path which requires the least number of jumps, and which also has the least physical distance is identified. FIG. 5 shows many of the same features shown in FIG. 4 and like features are awarded the same reference numbers.

For each of the good devices which are within the jump value of the first reference die 43, a score ‘F’ is calculated. This score ‘F’ is used to find the path (i.e. the order in which good dies on the wafer are picked (picking the designated first good die to the picked first) so that all good dies can be picked from the wafer) with the minimum number of jumps and the minimum physical distance the pickup head (or wafer) is required to move. The score ‘F’ is defined by a cost function, which combines a heuristic estimate of the cost to reach a first pickable die 44 and the distance travelled from the reference die 43. Specifically the score ‘F’ is defined by a cost function:

F=G+H

Here, ‘G’ is the known cost of getting from the reference die 43; and ‘H’ is a heuristic estimate of the cost to get from a die (n) to the next pickable die and/or first die to be picked.

For each of the good devices which are within the jump value of the first reference die 43, a score (F), is calculated (i.e. for each of the good dies which are within ‘3’ dies from the first reference die 43 a score (F) is calculated). The pickup head then jumps to the die which has the lowest score (F). Once the pickup head has jumped to the die, a score (F) is calculated for each of the good devices which are within the jump value of that die; and the pickup head then jumps to the die which has the lowest score (F). These steps are repeated until the pickup head is centered over a die which is within ‘3’ dies of the first die to be picked 44; the pickup head is then moved from that die to the first die to be picked 44 and is centered over the first die to be picked 44. The pickup head is then moved to pick the first die to be picked 44.

After the first die to be picked 44 has been picked, the same steps are repeated to moved from the position of the first die to be picked 44 to the position of a second die to be picked. The steps are repeated until all the good dies (or a predefined number of good dies) have been picked from the wafer 40.

As mentioned in the method of the present invention the pickup head jumps to the die which has the lowest score (F). The score (F) for each good die on the wafer 40, which is within ‘3’ dies from the first reference die 43 (i.e. all good dies which are within a ‘jump value’ number of dies from the first reference die 43) or which are within ‘3’ dies (i.e. “jump value”) of a subsequent die over which the pickup head has been centered, can be calculated in any suitable pathfinder techniques. However in a preferred embodiment the score for each good die is calculated by the following formula:

(F)=(G)+(H)

wherein ‘F’ is the score for a die, cost ‘G’ is the movement cost to move the pickup head to said die (e.g. the movement cost to move the pickup head from the first reference die to said die), and cost ‘H’ is the estimated movement cost to move from said die to the die which is to be picked (e.g. the estimated movement cost to move from said die to the first die to be picked 44). Thus in the method of the present invention the pickup head jump to (i.e. is moved to be centered above) the good die which has the lowest score ‘F’.

In order to illustrate the embodiment more clearly a frame of reference 49 showing an x-axis and y-axis is illustrated in FIG. 5. In this example in order to calculate ‘G’ cost for a given die on the wafer 40, a cost of ‘1’ is assigned to each die over which the pickup head moves along the x-axis, and a cost of ‘1’ is assigned to each die over which the pickup head moves along the y-axis; a cost of ‘1.4’ is assigned to each die over which the pickup head moves along the diagonal. It will be understood that any values may be assigned to each cost and that the present invention is not limited to requiring the use of cost values of ‘1’, ‘1’ and “1.4’.

To calculate the ‘G’ cost of a good die on the wafer 40, is to take the ‘G’ cost of the die over which the pickup head is currently centered, and then add ‘1’ or ‘1.4’ depending on whether a diagonal or orthogonal (non-diagonal) movement is required to move to the die. It should be noted that the ‘G’ cost of the first reference die 43 is ‘0’. For example in FIG. 5, the first reference die 43 has a ‘G’ cost of ‘0’, the ‘G’ cost of good die 41g is ‘1’ as in order to get from the first reference die 43 to the good die 41g the pickup head is required to move one die along the y-axis; the ‘G’ cost of good die 41f is ‘2’ as in order to get from the first reference die 43 to the good die 41f the pickup head is required to move two die along the y-axis; the ‘G’ cost of good die 41m is ‘1’ as in order to get from the first reference die 43 to the good die 41m the pickup head is required to move one die along the x-axis; the ‘G’ cost of good die 41t is ‘3’ as in order to get from the first reference die 43 to the good die 41t the pickup head is required to move three die along the y-axis; the ‘G’ cost of good die 41k is ‘2.24’ as in order to get from the first reference die 43 to the good die 41k the pickup head is required to move two die along the y-axis plus one die along the x-axis (i.e. using pythagoras theorem ‘square root of (2²+1²)’.

The estimated cost H of a die on the wafer can be estimated in a variety of ways. In one embodiment of present invention in order to calculate the estimated cost H of a good die on the wafer 40, the total number of dies over which the pickup head must move, in order to get from the die to the next die which is to be picked, by moving exclusively orthogonal (non-diagonal) movement, and including and bad dies 42a-c. For example in FIG. 5, the good die 41m has a estimated cost H of ‘3’ since in order to move from the good die 41m to the first die to be picked 44 the pickup head must move ‘3’ dies along the x-axis (i.e. bad die 42d-good die 41t-first die to be picked 44); the good die 41t has a estimated cost H of ‘1’ since in order to move from the good die 41m to the first die to be picked 44 the pickup head must move 1 die along the x-axis; the good die 41k has a estimated cost H of ‘3.61’ since in order to move from the good die 41k to the first die to be picked 44 the pickup head must move ‘3’ dies along the x-axis plus ‘2’ dies along the y-axis, which using (i.e. using pythagoras theorem ‘square root of (3²+2²))’ gives a estimated cost H of 3.61.

In order to calculate the score F for a good die, the cost G and cost H for that good die are added. In FIG. 5 the cost G of each good die which is within ‘3’ dies (i.e. ‘jump value’) of the first reference die 43 is shown in the bottom left corner of each die; the estimate cost H of each good die which is within ‘3’ dies (i.e. ‘jump value’) of the first reference die 43 is shown in the bottom right corner of each die; and the corresponding score F for each die is shown in the top right corner of each good die.

In the example shown in FIG. 5 the good die 41m has the lowest score F, thus according to the present invention the wafer will be moved under the pickup head so that the pickup head jumps from the first reference die 43 to the good die 41m and will be centered above the good die 41m (i.e. the pickup head will jump from the first reference die 43 to the good die 41m). By jumping to the good die 41m which has the lowest score F the pickup head will move along a path which fulfils the conditions of requiring the lowest number of jumps and is the shortest physical distance between the first reference die 43 and the first die to be picked 44. After the pickup head has been centered above the good die 41m, and without having picked the good die 41m from the wafer 40, the pickup head will then move from the good die 41m directly to the first die to be picked 44; the pickup head will be centered above the first die to be picked 44 and the pickup head will pick the die 44.

However, in another scenario, as illustrated in FIG. 5, more than one good die could get the same score F (i.e. 41m and 41t in FIG. 5). In this case, the eligible die will be selected by taking the lowest estimated cost H so that the pickup head is moved to go as close as possible to the targeted first pickable die 44.

After the die 44 has been picked the above mentioned steps will be repeated so that the pickup head is moved to be centered above a second good die to be picked. Specifically, for each of the good die which are within the jump value of the die 44, a score F, is calculated (i.e. for each of the good dies which are within ‘3’ dies from the die 44 a score F is calculated). The pickup head then jumps to the die which has the lowest score F. Once the pickup head has jumped to the die, a score F is calculated for each of the good die which are within the jump value of that die; and the pickup head then jumps to the die which has the lowest score F; these steps are repeated until the pickup head is centered over a die which is within ‘3’ dies of the second die to be picked; the pickup head is then moved from that die to the second die to be picked and is centered over the second die to be picked. The pickup head is then moved to pick the second die to be picked.

These steps will be repeated for each of the good dies on the wafer which are to be picked, until all of the good dies which are to be picked have been picked from the wafer 40.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. A method of handling components on a carrier, the method comprising the steps of,
providing a carrier having a plurality of components supported thereon;
testing the plurality of components to identify good components and bad components, wherein good components are those components which successfully pass testing and bad components are those components which fail testing;
defining a first good components to be picked from the carrier;
defining an integer number of components to be a jump value;
locating a pickup head, which is operable to pick components from the carrier, above a first reference position on the carrier;
identifying one or more good components, which are within the jump value from the first reference position;
moving the pickup head or the carrier so that the pickup head is centered above at least one of the one or more good components;
moving the pickup head or the carrier, so that the pickup head is moved from above said at least one of the one or more good components to above the defined first good component to be picked without picking said at least one of the one or more good components;
centering the pickup head above the first good components to be picked;
picking the first good components to be picked.

2. A method according to claim 1 wherein the carrier is a wafer and the components comprise dies provided on the wafer.

3. A method according to claim 1 wherein the step of defining an integer number of components to be a jump value comprises, defining an integer number of components greater than ‘1’ to be a jump value.

4. A method according to claim 1, wherein the method comprises identifying a plurality of good components, which are within the jump value from the first reference position; and wherein the method comprises moving the pickup head so that it is consecutively centered above at least two good components, before moving the pickup head to above the defined first good component to be picked, without having picked any of said at least two good components.

5. A method according to claim 1, wherein the method comprises identifying all of good components which are within the jump value from the first reference position, and the method further comprises the steps of,
determining a path, between the first reference position and the first good component to be picked, which requires the pickup head to undergo the least number of jumps in order to move from the first reference position to the first good component to be picked, wherein a jump comprises moving the pickup head over an integer number of components less than or equal to the jump value, and centering the pickup head above a component; and
wherein the method comprises the steps of moving the pickup head so that it is centered above one or more good components which are positioned on said determined path which requires the pickup head to undergo the least number of jumps, before moving the pickup head to above the defined first good component to be picked.

6. A method according to claim 1, wherein the method comprises identifying all of good components, which are within the jump value from the first reference position, and the method further comprises the steps of,
determining a path which has the shortest distance, between the first reference position and the first good component to be picked;
and wherein the method comprises the steps of moving the pickup head so that it is centered above one or more good components which are positioned on said determined path, before moving the pickup head to above the defined first good component to be picked.

7. The method according to claim 1, comprising,
(a) determining a score (F) for each good component which is within the jump value from the first reference position, by, for each good component, adding a cost value (G) which is representative of the cost of moving the pickup head from its first reference position to said component, plus a cost value (H) which is representative of the estimated cost to move from said component to the first component which is to be picked
(b) moving the pickup head so that it is centered above the component which has the lowest (F) score;
(c) if the component which has the lowest score is within the jump value from the first component to be picked, then moving the pickup head from the component which has the lowest score to the first component to be picked; if the component which has the lowest score is not within the jump value from the first component to be picked, then determining a score (F) for each good component which is within the jump value from said component, by, for each good component, adding a cost value (G) which is representative of the cost of moving the pickup head from its current position to said component, plus a cost value (H) which is representative of the estimated cost to move from said component to the first component which is to be picked, and moving the pickup head so that it is centered above the component which has the lowest score (F), and repeating these steps until the pickup head is centred above a component which is within the jump value from the first component to be picked.

8. The method according to claim 1, further comprising the steps of,
(a) identifying one or more good components, which are within the jump value from the component over which the pickup head is centered;
(b) moving the pickup head so that it is centered above at least one of the identified one or more good components;
(c) moving the pickup head from above said at least one of the one or more good components to above another good component to be picked without picking said at least one of the one or more good components;
(d) centering the pickup head above said other good component to be picked;
(e) picking said other good component to be picked;
(f) repeating the steps a-e until a predefined number of components have been picked from the carrier.

9. The method according to claim 1 further comprising the steps of
(a) identifying one or more good components, which are within the jump value of the position which was occupied by the first good component to be picked;
(b) moving the pickup head so that it is centered above at least one of the identified one or more good components;
(c) moving the pickup head from above said at least one of the one or more good components to above a second good component to be picked without picking said at least one of the one or more good component;
(d) centering the pickup head above the second good component to be picked;
(e) picking the second good component to be picked.

10. The method according to claim 1 wherein the method further comprises the steps of,
generating a map file having data which represents the positions of the good components and the positions of bad components on the carrier, and wherein the map file for a respective carrier is generated prior to picking any components from that carrier; and
using the map file to, identify one or more good components which are within the jump value of the first reference position, and/or identify one or more good components which are within the jump value of a component over which the pickup head is centered.

11. The method according to claim 1 wherein the first reference position on the carrier is a position which the pickup head is centered over, is defined by a fiducial on the carrier, or is a predefined component on the carrier.

12. A component handling apparatus, comprising,
a pickup head which is operable to pick components from a carrier; and
a data processing means which is programed to implement the method according to claim 1.
